(19) United States
(12) Patent Application Publication
(10) Pub. No.: US 2025/0133699 A1
(43) Pub. Date: Apr. 24, 2025

(54) ELECTRONIC DEVICE

(71) Applicants: Chien-Sheng Lan, Taipei City (TW); Ying-Chieh Wu, Taipei City (TW); Chih-Yuan Chuang, Taipei City (TW); Wen-Hsien Chin, Taipei City (TW); Yi-Chang Lee, Taipei City (TW); Jih-Houng Lee, Taipei City (TW)

(72) Inventors: Chien-Sheng Lan, Taipei City (TW); Ying-Chieh Wu, Taipei City (TW); Chih-Yuan Chuang, Taipei City (TW); Wen-Hsien Chin, Taipei City (TW); Yi-Chang Lee, Taipei City (TW); Jih-Houng Lee, Taipei City (TW)

(73) Assignee: COMPAL ELECTRONICS, INC., Taipei City (TW)

(21) Appl. No.: 18/408,600

(22) Filed: Jan. 10, 2024

Related U.S. Application Data
(60) Provisional application No. 63/544,951, filed on Oct. 20, 2023.

(51) Int. Cl. H05K 7/20; G06F 1/16; G06F 1/20

(52) U.S. Cl. CPC H05K 7/2039; G06F 1/166; G06F 1/203

(57) ABSTRACT

An electronic device includes a logic body, a heat dissipation fin, and a rotating bracket. The logic body has multiple first end openings and multiple first bottom openings. The first end openings are disposed on a first end of the logic body. The first bottom openings are disposed on a bottom of the logic body and are adjacent to the first end. The heat dissipation fins are disposed inside an interior of the logic body and correspond to the first bottom openings. The rotating bracket is rotatably disposed at the bottom. In a closed mode, the rotating bracket is close to the bottom and covers the first bottom openings. In an open mode, the rotating bracket is unfolded from the bottom and exposes the first bottom openings.

### CROSS-REFERENCE TO RELATED APPLICATION

This application claims the priority benefit of U.S. provisional application Ser. No. 63/544,951, filed on Oct. 20, 2023. The entirety of the above-mentioned patent application is hereby incorporated by reference herein and made a part of this specification.

### BACKGROUND

### Technical Field

The disclosure relates to an electronic device, and particularly relates to an electronic device improving heat dissipation efficiency.

### Description of Related Art

There is a growing demand for higher performance for the conventional electronic device such as laptop or tablet. However, higher performance means generating more heat, so the heat dissipation efficiency of the high-performance electronic device needs to be synchronously improved. For the conventional electronic device, the heat source such as a central processing unit, a graphics chip, and a hard drive are usually installed inside a logic body. The heat of the heat source is absorbed by the built-in heat dissipation fin, then the cold air is pumped into the logic body through the fan, and heat is swapped with the heat dissipation fin in order to dissipate heat.

The logic body of the conventional laptop is raised through multiple foot pads, so a gap is formed between the logic body and the resting surface, which provides a space for the circulation of hot and cold air. However, the space formed by the foot pads cannot provide enough air flow, which is insufficient to improve the heat dissipation efficiency.

### SUMMARY

The disclosure provides an electronic device. The orientation of a support stand may be adjusted according to the usage requirement to switch to a closed mode or an open mode. In the open mode, the heat dissipation efficiency can be improved and an included angle of the electronic device may be adjusted to be ergonomically sound.

The electronic device according to the disclosure includes a logic body, a heat dissipation fin, and a rotating bracket. The logic body has multiple first end openings and multiple first bottom openings. The first end openings are disposed on a first end of the logic body. The first bottom openings are disposed on a bottom of the logic body and are adjacent to the first end. The heat dissipation fins are disposed inside an interior of the logic body and correspond to the first bottom openings. The rotating bracket is rotatably disposed at the bottom. In a closed mode, the rotating bracket is close to the bottom and covers the first bottom openings. In an open mode, the rotating bracket is unfolded from the bottom and exposes the first bottom openings.

Based on the above, the electronic device according to the disclosure adopts the rotating bracket. In the closed mode, the rotating bracket is close to the bottom to reduce the size. The electronic device is suitable for low-performance usage scenarios such as browsing a web page or watching a video. In the open mode, the rotating bracket is unfolded from the bottom to increase the space for heat dissipation. The electronic device is suitable for full-performance usage scenarios such as gaming, graphics, or programming.

Furthermore, the rotating bracket according to the disclosure corresponds to the first bottom openings and the heat dissipation fins, and has a characteristic of a shorter length, so the flipping stroke of the rotating bracket is also shorter. In the process of switching to the open mode, the logic body may be slightly raised with one hand while the rotating bracket may be fully unfolded with the other hand to have the advantages of a smaller unfolding action and effort saving.

In addition, when the logic body is lifted by the rotating bracket, the included angle between the logic body and a plane is ergonomically sound, therefore allowing the user to use a keyboard of the logic body for a long period of time.

### BRIEF DESCRIPTION OF THE DRAWINGS

FIG. 1A is a schematic three-dimensional view of an electronic device in a closed mode according to an embodiment of the disclosure.

FIG. 1B is a schematic perspective plane view of some elements of the electronic device in FIG. 1A in the closed mode.

FIG. 1C is a schematic side plane view of the electronic device in FIG. 1A in the closed mode.

FIG. 1D is a schematic three-dimensional view of the electronic device in FIG. 1A in an open mode.

FIG. 1E is a schematic side plane view of the electronic device in FIG. 1C switched to the open mode.

FIG. 2A is a schematic plan view of an electronic device with a grid perforation added on a rotating bracket according to another embodiment of the disclosure.

FIG. 2B is a schematic three-dimensional cross-sectional view of some elements of the electronic device in FIG. 2A.

FIG. 2C is a schematic three-dimensional perspective view of some elements of the electronic device in FIG. 2A.

FIG. 2D is a schematic three-dimensional view of the electronic device in FIG. 2A in an open mode.

FIG. 3 is a schematic plan view of an electronic device with a changed orientation of a rotating bracket according to another embodiment of the disclosure.

FIG. 4A is a schematic three-dimensional view of an electronic device in a closed mode according to another embodiment of the disclosure.

FIG. 4B is a schematic three-dimensional view of the electronic device in FIG. 4A in an open mode.

FIG. 5A to FIG. 5C are schematic views of actions of the electronic device in FIG. 4A switching from the closed mode to the open mode.

FIG. 6A to FIG. 6C are schematic views of actions of switching from a closed mode to an open mode according to another embodiment of the disclosure.

FIG. 7A to FIG. 7C are schematic views of actions of an electronic device switching from a closed mode to an open mode according to another embodiment of the disclosure.

FIG. 8A to FIG. 8C are schematic views of actions of an electronic device switching from a closed mode to an open mode according to another embodiment of the disclosure.

### DESCRIPTION OF THE EMBODIMENTS

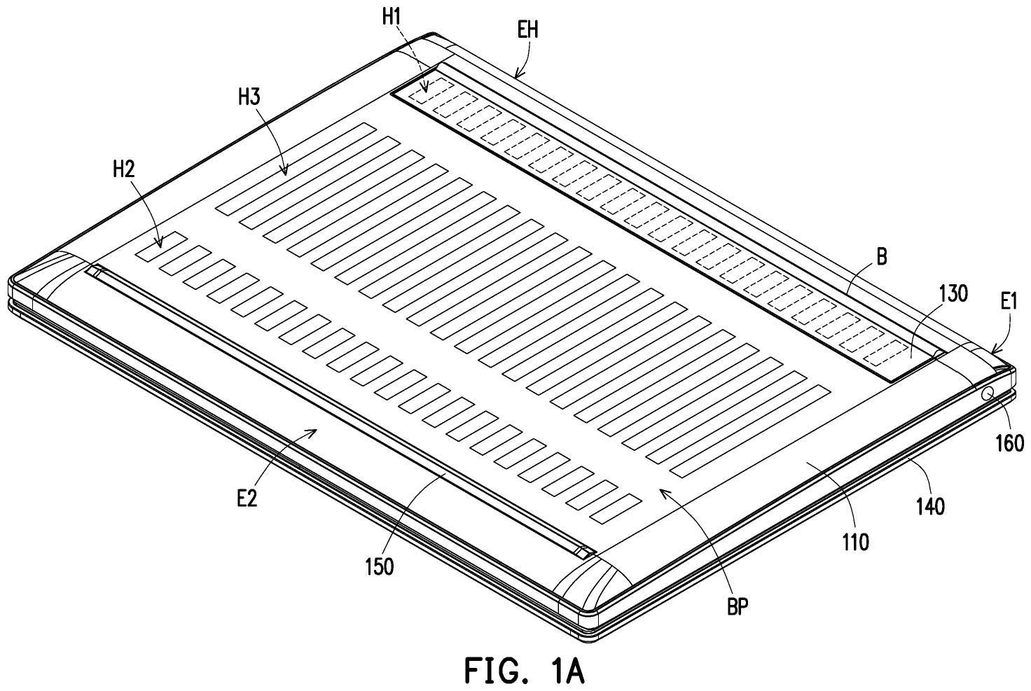

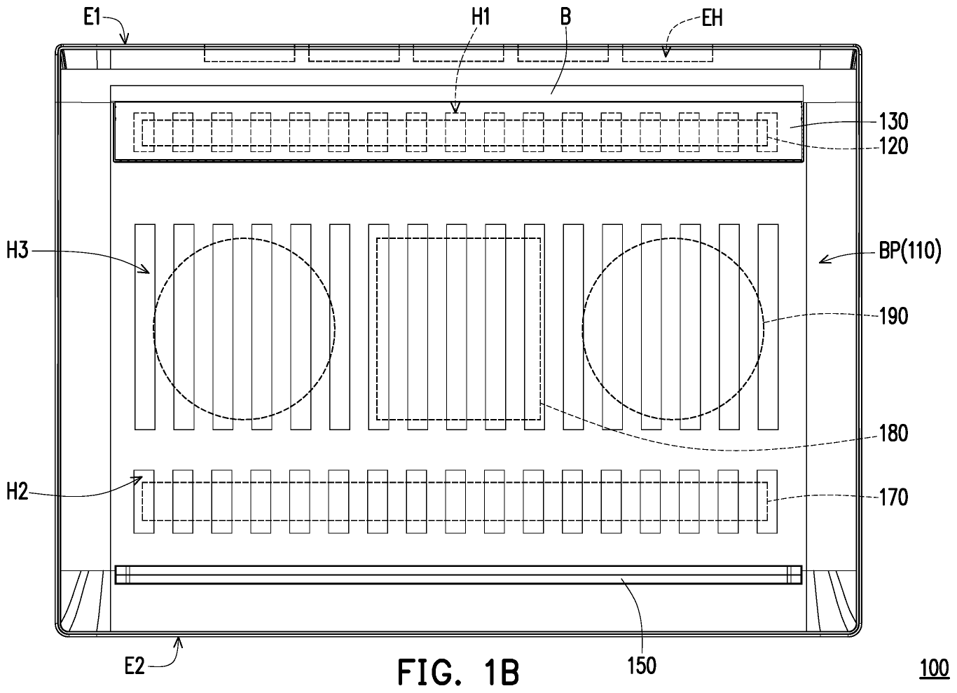

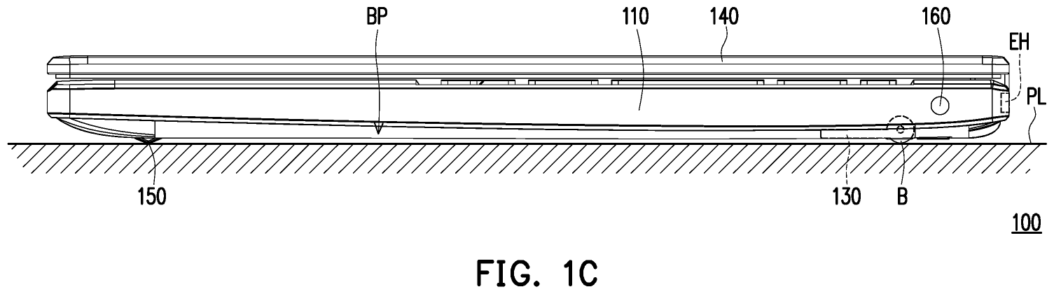

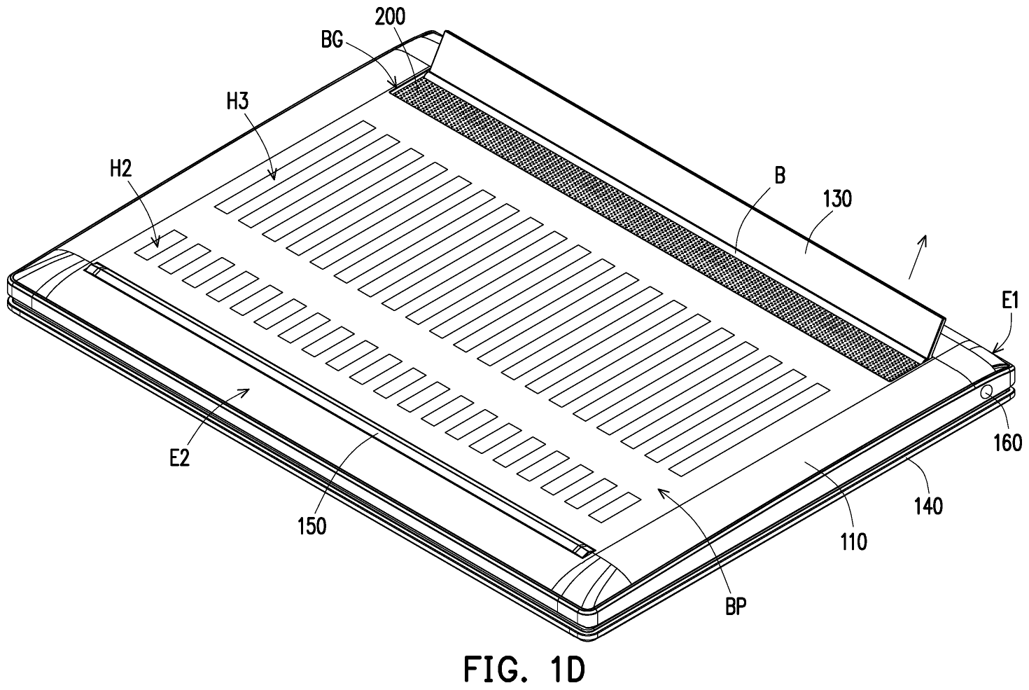

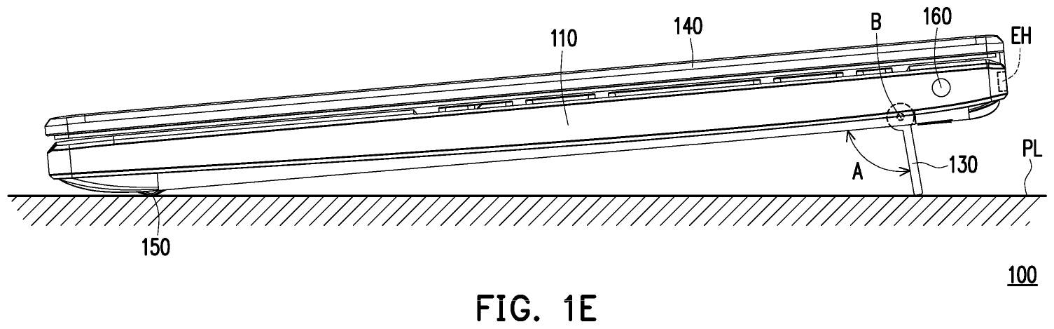

FIG. 1A is a schematic three-dimensional view of an electronic device in a closed mode according to an embodiment of the disclosure. FIG. 1B is a schematic perspective plane view of some elements of the electronic device in FIG. 1A in the closed mode. FIG. 1C is a schematic side plane view of the electronic device in FIG. 1A in the closed mode. FIG. 1D is a schematic three-dimensional view of the electronic device in FIG. 1A in an open mode. FIG. 1E is a schematic side plane view of the electronic device in FIG. 1C switched to the open mode.

Referring to FIG. 1A and FIG. 1B, the electronic device in the embodiment is, for example, a laptop, a tablet, a server, a home game console, a desktop computer, a personal computer, an artificial intelligence personal computer (AI PC), or other similar electronic equipment.

An electronic device 100 according to the disclosure includes a logic body 110, a heat dissipation fin 120, and a rotating bracket 130.

Referring to FIG. 1A, FIG. 1B, and FIG. 1D, the logic body 110 has multiple first end openings EH and multiple first bottom openings H1. The first end openings EH are disposed on a first end E1 of the logic body, wherein the first end openings EH are air outlets and are used to discharge the hot air inside the logic body 110. In the actual application, the first end may be near a user end, near a shaft end, a left-side end, or a right-side end, but the disclosure is not limited thereto. The first bottom openings H1 are disposed on a bottom BP of the logic body 110 and are adjacent to the first end E1, wherein the first bottom openings H1 are air inlets and are used to pump the cold air from the environment into the logic body 110.

Referring to FIG. 1B, the heat dissipation fin 120 is disposed inside an interior IS of the logic body and corresponds to the first bottom openings H1. The rotating bracket 130 is rotatably disposed at the bottom BP.

Referring to FIG. 1A to FIG. 1C, in a closed mode, the rotating bracket 130 is close to the bottom BP and covers the first bottom openings H1, wherein a gap is between the rotating bracket 130 and the bottom BP of the logic body 110. Referring to FIG. 1D and FIG. 1E, in an open mode, the rotating bracket 130 is unfolded from the bottom BP and exposes the first bottom openings H1. In addition, in the open mode, the rotating bracket 130 has a characteristic of shorter length, so the flipping stroke of the rotating bracket 130 is also shorter and the angle of the logic body 110 being raised is smaller, so the included angle between the logic body 110 and a plane PL is ergonomically sound, therefore allowing the user to use a keyboard of the logic body for a long period of time.

Specifically, the electronic device 100 further includes a display machine 140 and multiple foot pads 150. The display machine 140 may be pivotally, detachably, or pivotally and detachably disposed on the first end E1. The foot pads 150 are disposed on the bottom BP and are away from the first end E1, wherein the foot pads are made of a rubber material.

In addition, the display body 140 includes a display panel or a touch display panel. The display panel is a liquid crystal display panel, a light-emitting diode display panel, an organic light-emitting diode display panel, or an electrophoretic display panel. The touch display panel is a capacitive touch display panel, a resistive touch display panel, an optical touch display panel, or an acoustic wave touch display panel.

In an embodiment, referring to FIG. 1A, the electronic device 100 further includes a release button 160 and a torsion spring (not shown), the release button 160 is disposed on a side of the logic body 110, and the torsion spring links the rotating bracket 130 and the release button 160. When the release button 160 is pressed by an external force, a limit on the torsion spring is released, and the torsion spring is elastically recovered to drive the rotating bracket 130 to be unfolded from the bottom BP of the logic body 110, that is, to automatically switch to the open mode to raise the logic body 110 and increase the air intake volume of the first bottom openings H1.

Referring to FIG. 1D, the logic body 110 has a bottom groove BG surrounding the first bottom openings H1. Referring to FIG. 1A, in the closed mode, the rotating bracket 130 is accommodated in the bottom groove BG to cover the first bottom openings H1. Referring to FIG. 1D, in the open mode, the rotating bracket 130 is unfolded relative to the logic body 110 and is away from the bottom groove BG, and the rotating bracket 130 is used to prevent the hot air discharged by the first end openings EH from flowing back to the first bottom openings H1.

Referring to FIGS. 1A and 1B, the logic body 110 has multiple second bottom openings H2 away from the first bottom openings H1. Specifically, the second bottom openings H2 are disposed on the bottom BP of the logic body 110 and are near to a second end E2 opposite to the first end E1. The logic body 110 further includes a storage unit 170 disposed inside the interior and corresponding to the second bottom openings H2. The storage unit is a memory or a hard drive and the second bottom openings H2 are air inlets and are used to pump the cold air from the environment into the logic body 110.

Referring to FIG. 1A and FIG. 1B, the logic body 110 has multiple third bottom openings H3 adjacent to the first end openings H1, and the third bottom openings H3 are air inlets and are used to pump the cold air from the environment into the logic body 110. The third bottom opening H3 is located between each first bottom opening H1 and each second bottom opening H2.

Referring to FIG. 1A and FIG. 1B, a size of each first bottom opening H1 is smaller than a size of each third bottom opening H3, and a size of each second bottom opening H2 is smaller than the size of each third bottom opening H3. An aperture ratio of the first bottom openings H1 is smaller than an aperture ratio of the third bottom openings H3, and an aperture ratio of the second bottom openings H2 is smaller than the aperture ratio of the third bottom openings H3.

In addition, since the rotating bracket 130 has a shorter length, in the closed mode. the rotating bracket 130 does not cover the third bottom openings H3 and the second bottom openings H2. It is noted here that whether in the closed mode or the open mode, the third bottom openings H3 and the second bottom openings H2 are all exposed at the bottom BP of the logic body 110. Referring to FIG. 1A and FIG. 1D, a stopper B is further included and is disposed on the bottom and is located on a back surface of the rotating bracket 130. A number of the stopper B may be single or multiple. When the number of the stopper B is multiple, the stoppers B may be staggered or linearly arranged.

In an embodiment shown in FIG. 1A, the stopper B is integrally formed on the rotating bracket 130. The rotating bracket 130 and the stopper B are made of plastic, rubber, or plastic and rubber materials. Referring to FIG. 1B, the stopper B is disposed between the first end openings EH and the first bottom openings H1. Furthermore, in the closed mode, the stopper B protrudes from the bottom BP and is used to prevent the hot air discharged by the first end openings EH from flowing back to the first bottom openings H1.

Referring to FIG. 1B, the logic body 110 further includes a processing unit 180 and a heat dissipation fan 190. The processing unit 180 and the heat dissipation fan 190 are both disposed inside the interior IS and correspond to the third bottom openings H3.

The processing unit 180 is a central processing unit (CPU), a graphics processing unit (GPU), a data processing unit (DPU), a vision processing unit (VPU), a tensor processing unit (TPU), or a neural processing unit (NPU). The heat dissipation fan 190 is a radial direction heat dissipation fan or an axial direction heat dissipation fan.

Referring to FIG. 1D, a mesh element 200 is further included and is correspondingly disposed on at least one of the first bottom openings H1, the second bottom openings H2, and the third bottom openings H3. In other embodiments, the number of at least a mesh element 200 includes multiple, and the mesh elements 200 are respectively disposed on the first bottom openings H1, the second bottom openings H2, and the third bottom openings H3. The mesh element 200 has the effect of filtering dust and blocking and protecting internal elements.

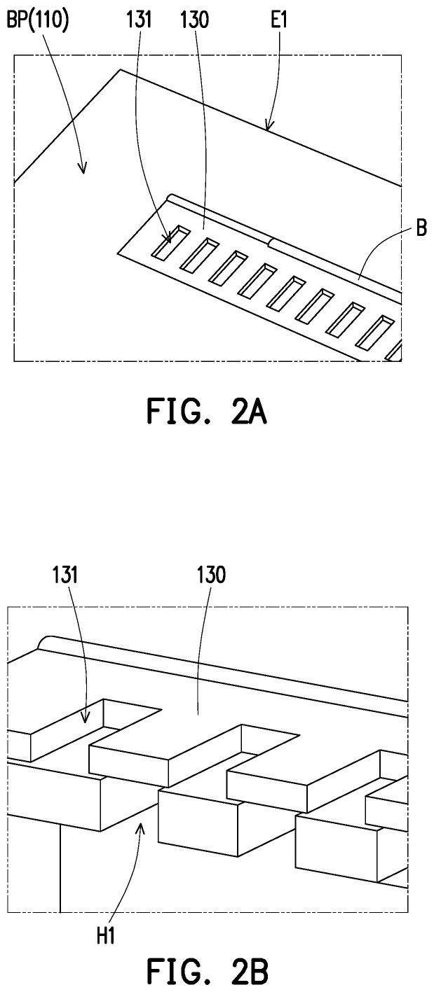

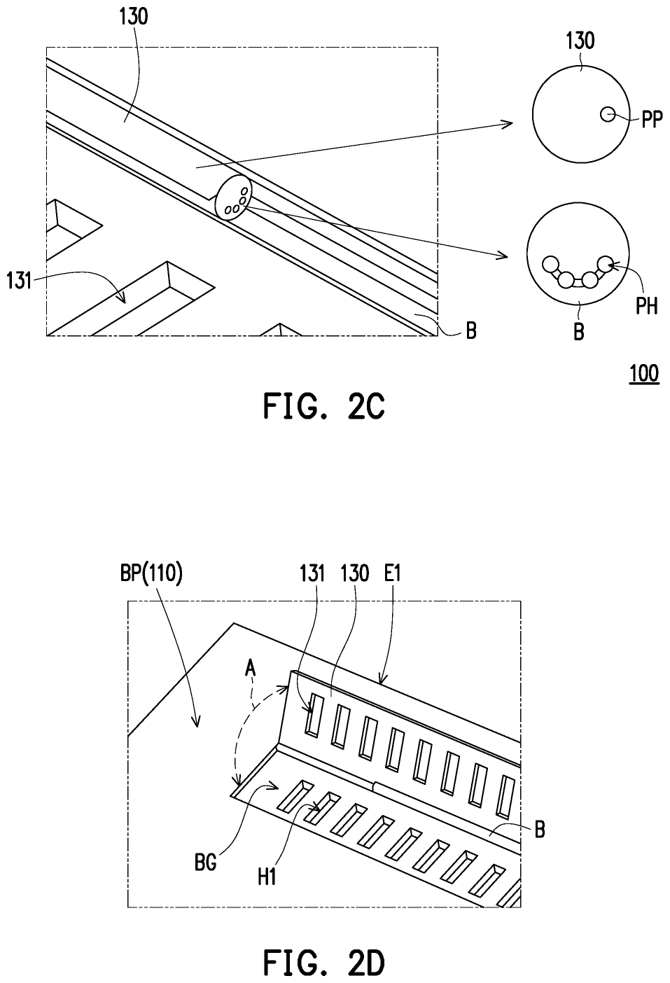

FIG. 2A is a schematic plan view of an electronic device with a grid perforation added on a rotating bracket according to another embodiment of the disclosure. FIG. 2B is a schematic three-dimensional cross-sectional view of some elements of the electronic device in FIG. 2A. FIG. 2C is a schematic three-dimensional perspective view of some elements of the electronic device in FIG. 2A.

Referring to FIG. 2A and FIG. 2B, the rotating bracket 130 has multiple grid perforations 131, and the rotating bracket 130 may be made of a plastic or metal material. In the closed mode, a gap is between the rotating bracket 130 and the bottom BP, and the grid perforations 131 are misaligned from the first bottom openings H1. Referring to FIG. 1E, in the open mode, the grid perforations 131 are away from the first bottom openings H1.

Furthermore, when the rotating bracket 130 is closed on the bottom BP of the logic body 110, the cold air from the outside may enter the interior IS of the logic body 110 through the grid perforations 131 and the first bottom openings H1 to reduce the interior temperature of the logic body 110. Therefore, in the closed mode, the logic body according to the embodiment has better appropriate heat dissipation effect compared to the logic body not equipped with the grid perforations 131. Furthermore, since the grid perforations 131 are misaligned from the first bottom openings H1, the first bottom openings H1 are blocked by the rotating bracket 130 to have a special appearance.

Referring to FIG. 2A to FIG. 2C, in the embodiment, the stopper B is disposed on the bottom BP of the logic body 110 and is adjacent to the first end E1, the stopper B may be made of a rubber material, and the rotating bracket 130 is pivotally connected to the stopper B. Multiple positioning holes PH are on the two sides of the stopper B, a positioning point PP is on the two sides of the rotating bracket 130, and each positioning point PP is adapted to be engaged with to one of the positioning openings PH to fix an unfolding angle A of the rotating bracket 130 relative to the bottom BP.

Furthermore, in an embodiment shown in FIG. 2C, the rotating bracket 130 has a multistage unfolding angle and may be slightly adjusted according to the user requirement, thereby raising the logic body 110 to the required height.

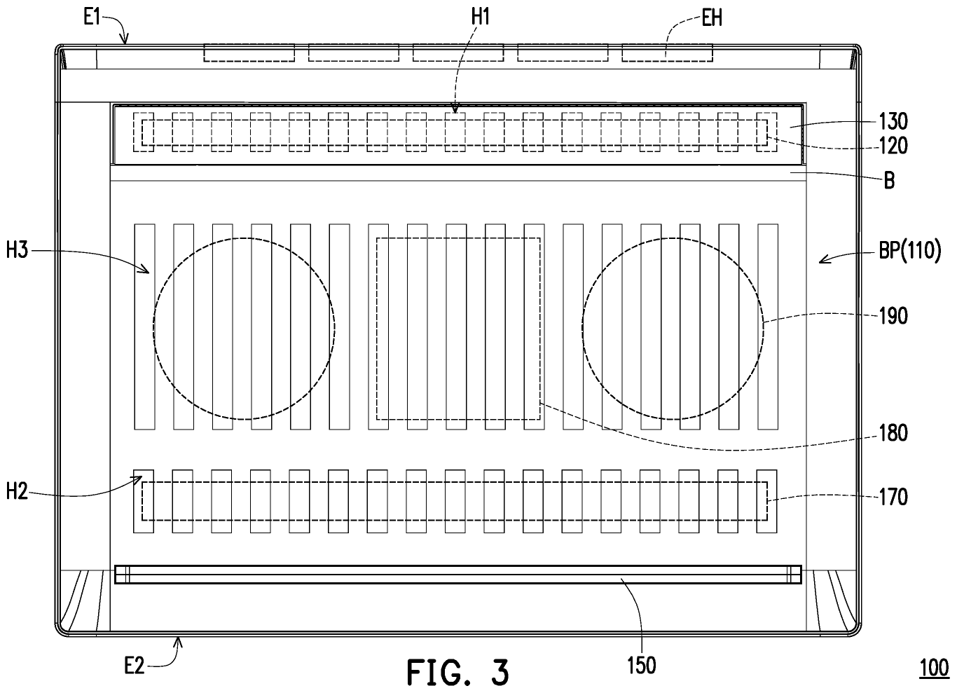

FIG. 3 is a schematic plan view of an electronic device with a changed orientation of a rotating bracket according to another embodiment of the disclosure. Referring to FIG. 3, in the embodiment, the first bottom openings H1 are disposed between the first end openings EH and the stopper B in order to install the stopper B on a central area of the logic body 110, which may be adjusted depending on the structural requirement.

Furthermore, in the closed mode, the stopper B protrudes from the bottom BP and is used to prevent the hot air discharged by the first end openings EH from flowing back to the third bottom openings H3 and the second bottom openings H2.

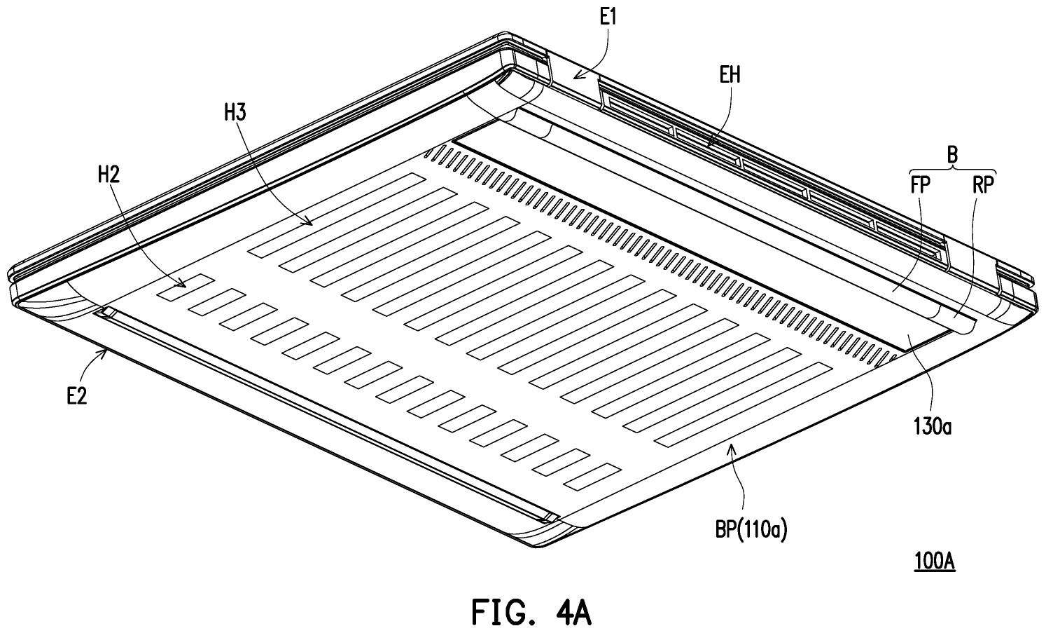

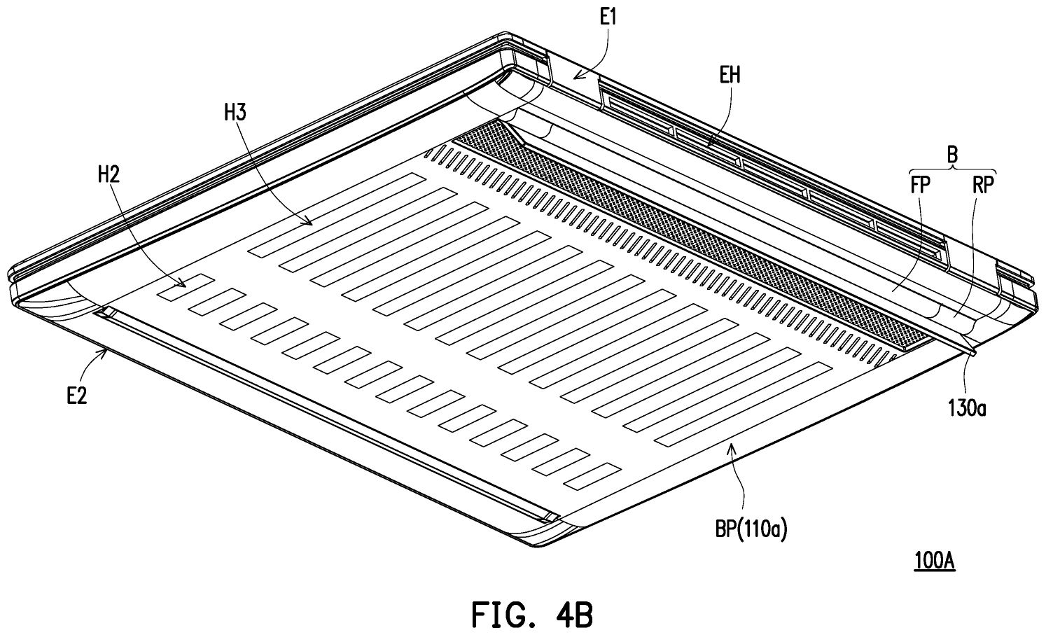

FIG. 4A is a schematic three-dimensional view of an electronic device in a closed mode according to another embodiment of the disclosure. FIG. 4B is a schematic three-dimensional view of the electronic device in FIG. 4A in an open mode.

Referring to FIG. 4A and FIG. 4B, in an electronic device 100A according to the embodiment, the stopper B is rotatably disposed at the bottom BP and a rotating bracket 130a may link the stopper B to rotate. Specifically, the stopper B has a fixed part FP and a rotating part RP. The fixed part FP is disposed on the bottom BP of the logic body 110a. The rotating part RP is disposed on the bottom BP and is rotatably connected to a side of the fixed part FP, and the rotating bracket 130a may link the rotating part RP to rotate. In short, when the rotating bracket 130a is unfolded relative to the bottom BP, the rotating part RP is synchronously driven, and then the unfolding angle of the rotating bracket 130a is supported through the rotating part RP. The rotating bracket 130a may cover a part of the first bottom openings H1 and expose another part of the first bottom openings H1, the third bottom openings H3, and the second bottom openings H2.

Furthermore, the rotating part RP adopts a composite graphic columnar rotating part and a convex polygonal columnar rotating part. A torsion spring is further included and is disposed between the fixed part FP and the rotating part RP to provide an elastic force to the rotating part RP for the user to easily open or close the rotating bracket 130a.

Furthermore, the numbers of the rotating part and the fixed part are both at least one, as shown in FIG. 4, when there are two rotating parts and one fixed part, the fixed part is disposed between the two rotating parts. In other embodiments, when there are two fixed parts and one rotating part, the rotating part is disposed between the two fixed parts.

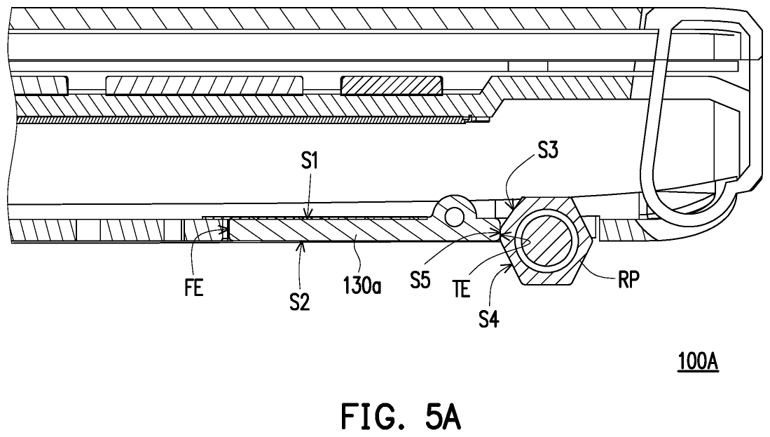

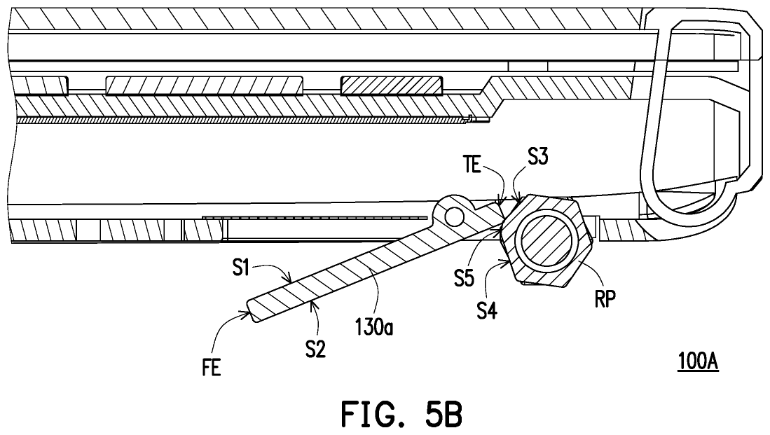

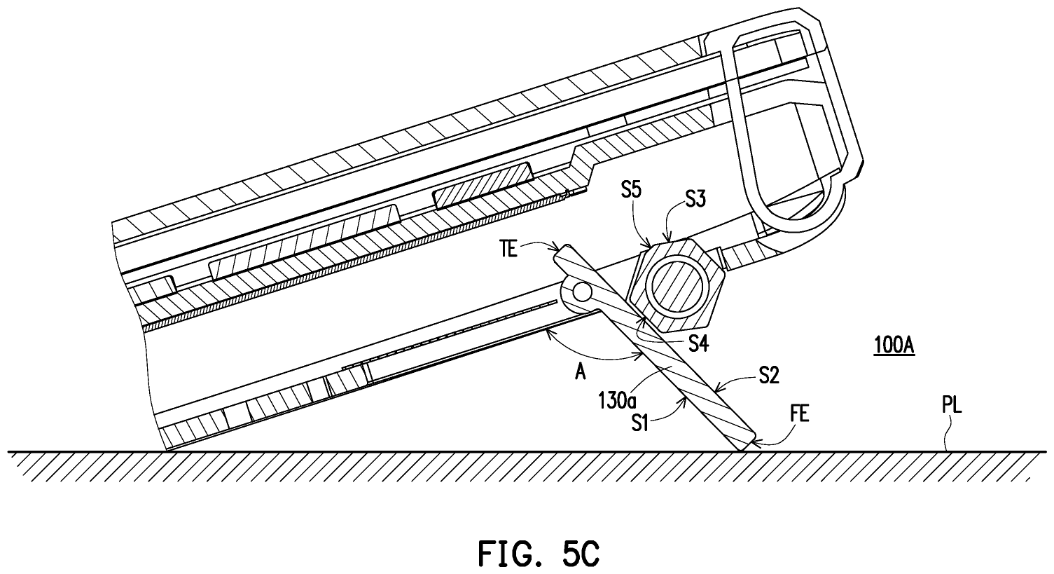

FIG. 5A to FIG. 5C are schematic views of actions of the electronic device in FIG. 4A switching from the closed mode to the open mode.

Referring to FIG. 5A, the rotating part RP of the electronic device 100A according to the embodiment adopts the composite graphic columnar rotating part, and a hexagonal rotating part is shown in FIG. 5A. The rotating bracket 130a has an end FE, a top TE, a ventral surface S1, and a back surface S2.

Referring to FIG. 5A, in the closed mode, the end FE of the rotating bracket 130a is away from the rotating part RP, the ventral surface S1 is close to the bottom BP, and the top TE of the rotating bracket 130a abuts against a stop surface S3 of each rotating part RP.

Referring to FIG. 5B, a linking process between the rotating bracket 130a and the stopper B is briefly described below. When the rotating bracket 130a is unfolded from the bottom BP, the top TE of the rotating bracket 130a pushes the stop surface S3 of each rotating part RP, so that the rotating part RP rotates relative to the fixed part FP until the back surface S2 of the rotating bracket 130a is close to a support surface S4 of each rotating part RP.

Referring to FIG. 5C, in the open mode, the end FE of the rotating bracket 130a abuts against an external plane PL, and the back surface S2 of the rotating bracket 130a is close to the support surface S4 of each rotating part RP in order to support the unfolding angle A of the rotating bracket 130a.

Furthermore, a length of the stop surface S3 is smaller than a length of the support surface S4, and a connection surface S5 is between the stop surface S3 and the support surface S4.

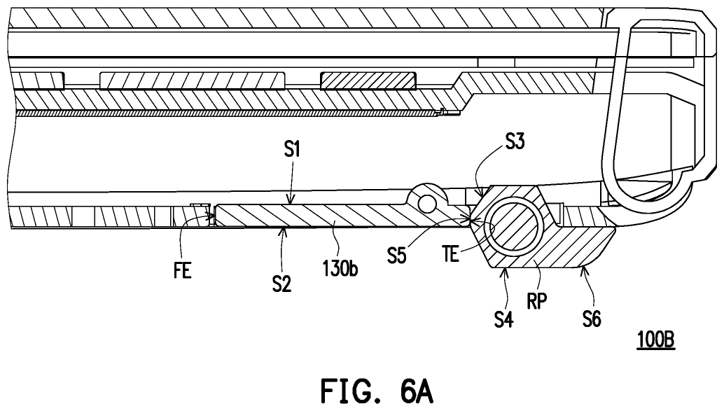

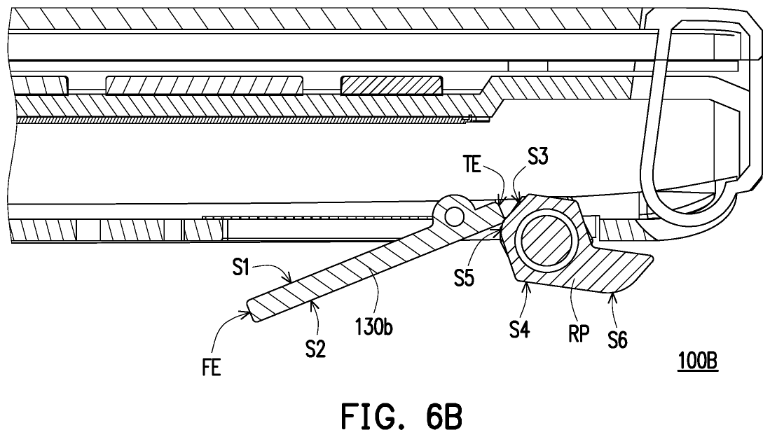

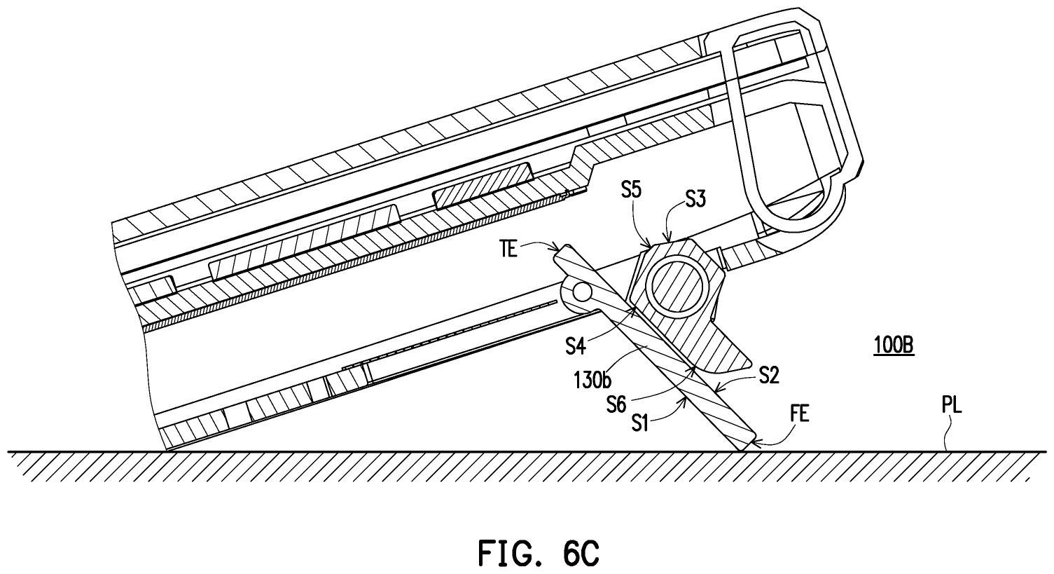

FIG. 6A to FIG. 6C are schematic views of actions of an electronic device switching from a closed mode to an open mode according to another embodiment of the disclosure.

Referring to FIG. 6A, the rotating part RP of an electronic device 100B according to the embodiment adopts a concave polygonal columnar rotating part and is presented as a concave polygonal magatama columnar rotating part or a magatama columnar rotating part. A rotating bracket 130b has an end FE, a top TE, a ventral surface S1, and a back surface S2.

Referring to FIG. 6A, in the closed mode, the end FE of the rotating bracket 130b is away from the rotating part RP, the ventral surface S1 is close to the bottom BP, and the top TE of the rotating bracket 130b abuts against a stop surface S3 of each rotating part RP.

Referring to FIG. 6B, a linking process between the rotating bracket 130b and the stopper B is briefly described below. When the rotating bracket 130b is unfolded from the bottom BP, the top TE of the rotating bracket 130b pushes the stop surface S3 of each rotating part RP, so that the rotating part RP rotates relative to the fixed part FP until the back surface S2 of the rotating bracket 130b is close to a support surface S4 and a magatama surface S6 of each rotating part RP.

Referring to FIG. 6C, in the open mode, the end FE of the rotating bracket 130b abuts against an external plane PL, and the back surface S2 of the rotating bracket 130b is close to the support surface S4 and the magatama surface S6 of each rotating part RP in order to support the unfolding angle of the rotating bracket 130b.

Furthermore, a length of the stop surface S3 is smaller than a length of the support surface S4, and a connection surface S5 is between the stop surface S3 and the support surface S4.

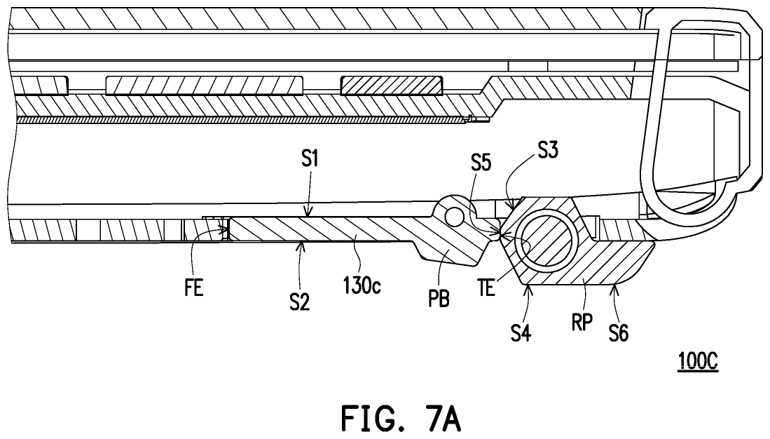

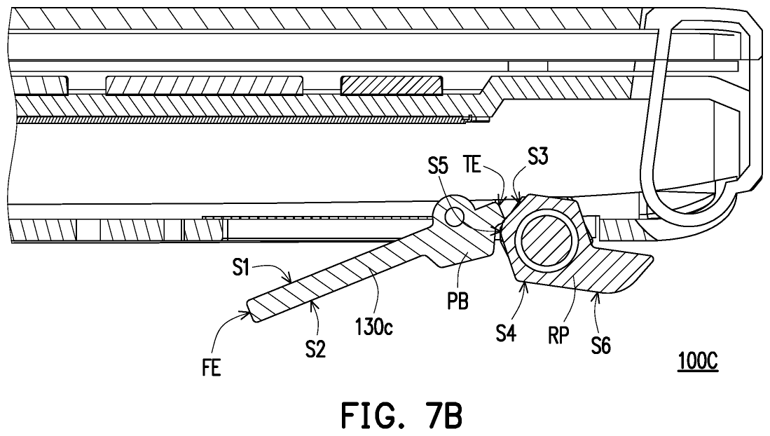

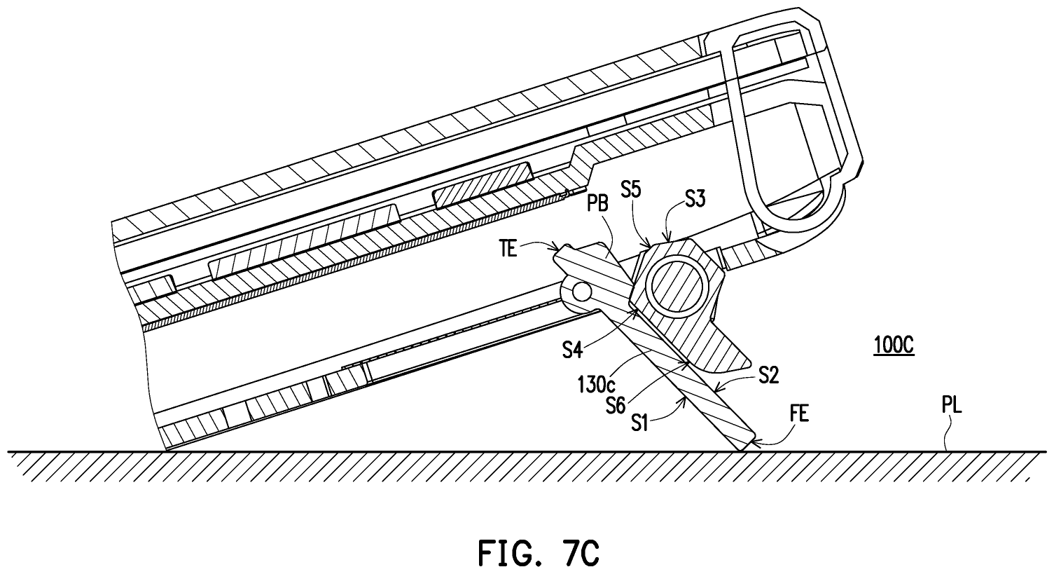

FIG. 7A to FIG. 7C are schematic views of actions of an electronic device switching from a closed mode to an open mode according to another embodiment of the disclosure.

Referring to FIG. 7A, the rotating part RP of an electronic device 100C according to the embodiment adopts the concave polygonal columnar rotating part and is presented as a concave polygonal magatama columnar rotating part or a magatama columnar rotating part. A rotating bracket 130c has an end FE, a top TE, a ventral surface S1, a back surface S2, and a bump BP. The bump PB is disposed on the back surface S2 and is adjacent to the top TE.

Referring to FIG. 7A, in the closed mode, the end FE of the rotating bracket 130c is away from the rotating part RP and the bump PB is separated from the rotating part RP, the ventral surface S1 is close to the bottom BP, and the top TE of the rotating bracket 130b abuts against a stop surface S3 of each rotating part RP. Furthermore, an inside surface of a protruding part of the magatama columnar rotating part RP is close to the bottom BP of a logic body 110c.

Referring to FIG. 7B, a linking process between the rotating bracket 130c and the stopper B is briefly described below. When the rotating bracket 130c is unfolded from the bottom BP, the top TE of the rotating bracket 130c pushes the stop surface S3 of each rotating part RP, so that the rotating part RP rotates relative to the fixed part FP until the back surface S2 of the rotating bracket 130c is close to a support surface S4 and a magatama surface S6 of each rotating part RP and the bump PB abuts against the rotating part RP.

Referring to FIG. 7C, in the open mode, the end FE of the rotating bracket 130c abuts against an external plane PL, the back surface S2 of the rotating bracket 130c is close to the support surface S4 and the magatama surface S6 of each rotating part RP, and the bump PB abuts against the rotating part RP. Furthermore, a backside surface of the protruding part of the magatama columnar rotating part is close to the back surface S2 of the rotating bracket 130c in order to support the unfolding angle of the rotating bracket 130c.

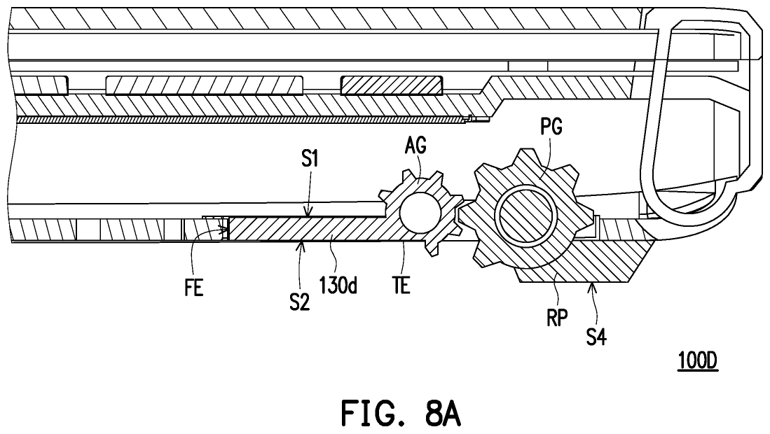

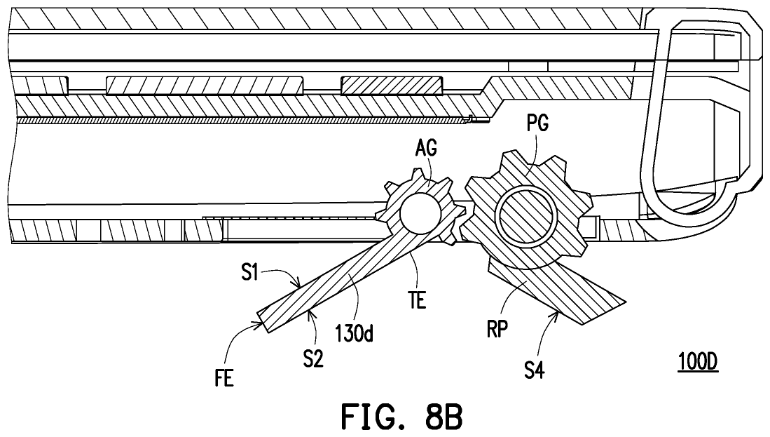

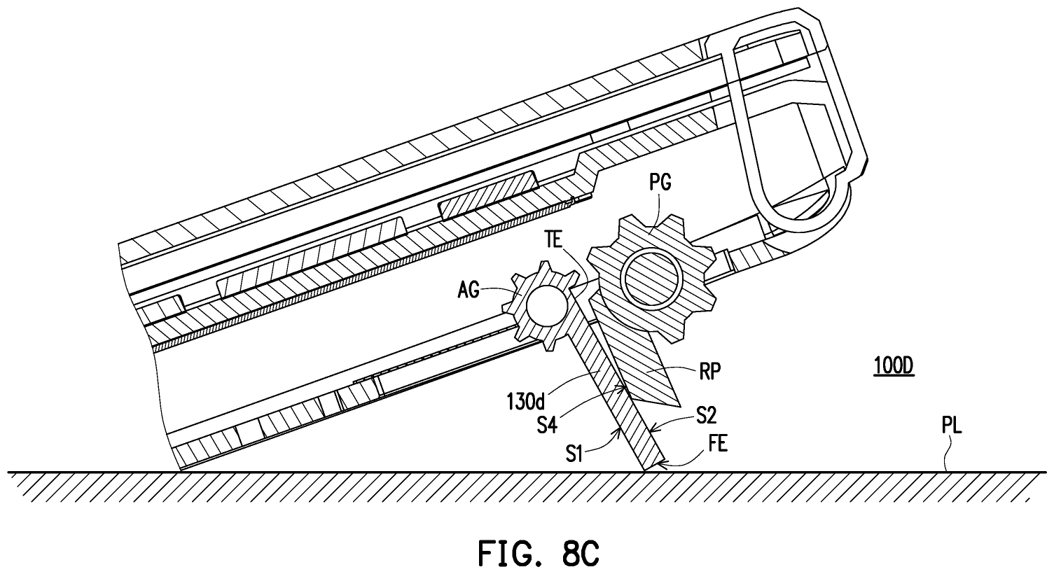

FIG. 8A to FIG. 8C are schematic views of actions of an electronic device switching from a closed mode to an open mode according to another embodiment of the disclosure.

Referring to FIG. 8A, the rotating part RP of an electronic device 100D according to the embodiment adopts the concave polygonal columnar rotating part, is presented as a concave polygonal magatama columnar rotating part or a magatama columnar rotating part, and has a passive gear part PG adjacent to a rotating bracket 130d. The rotating bracket 130d has an end FE, a top TE, a ventral surface S1, a back surface S2, and an active gear part AG. The active gear part AG is disposed on the top TE and is adjacent to the rotating part RP. The active gear part AG is adapted to be meshed with the passive gear part PG.

Referring to FIG. 8A, in the closed mode, the end FE of the rotating bracket 130d is away from the rotating part RP and the bump PB is separated from the rotating part RP, the ventral surface S1 is close to the bottom BP, and the active gear part AG of the rotating bracket 130c is meshed with the passive gear part PG of the rotating part RP.

Referring to FIG. 8B, a linking process between the rotating bracket 130d and the stopper B is briefly described below. When the rotating bracket 130d is unfolded from the bottom BP, the active gear part AG of the rotating bracket 130c drives the passive gear part PG of each rotating part RP, so that the rotating part RP rotates relative to the fixed part FP until the back surface S2 of the rotating bracket 130d is close to a support surface S4 of each rotating part RP.

Referring to FIG. 8C, in the open mode, the end FE of the rotating bracket 130d abuts against an external plane PL, the back surface S2 of the rotating bracket 130d is close to the support surface S4 of each rotating part RP, and the active gear part AG is separated from in the passive gear part PG.

Based on the above, the electronic device according to the disclosure adopts the rotating bracket. In the closed mode, the rotating bracket is close to the bottom to reduce the size. The electronic device is suitable for low-performance usage scenarios such as browsing a web page or watching a video. In the open mode, the rotating bracket is unfolded from the bottom to increase the space for heat dissipation. The electronic device is suitable for full-performance usage scenarios such as gaming, graphics, or programming.

Furthermore, the rotating bracket according to the disclosure corresponds to the first bottom openings and the heat dissipation fins and has a characteristic of a shorter length, so the flipping stroke of the rotating bracket is also shorter, so that when the user unfolds the rotating bracket, the logic body may be slightly raised with one hand while the rotating bracket may be fully unfolded with the other hand to have the advantages of a smaller switching action and effort saving.

In addition, when the logic body is lifted by the rotating bracket, the included angle between the logic body and the plane is ergonomically sound, therefore allowing the user to use the keyboard of the logic body for a long period of time.

In addition, a range of a groove in a back area of the logic body is smaller, so an accommodation space for electronic elements such as a fan module, a central processing unit, and a graphics processing unit inside the interior of the logic body is not easily compressed.

What is claimed is:

1. An electronic device, comprising:
a logic body, having a plurality of first end openings and a plurality of first bottom openings, wherein the first end openings are disposed on a first end of the logic body, and the first bottom openings are disposed on a bottom of the logic body and are adjacent to the first end;
a heat dissipation fin, disposed inside an interior of the logic body and corresponding to the first bottom openings; and
a rotating bracket, rotatably disposed at the bottom, wherein
in a closed mode, the rotating bracket is close to the bottom and covers the first bottom openings; and
in an open mode, the rotating bracket is unfolded from the bottom and exposes the first bottom openings.

2. The electronic device according to claim 1, wherein the logic body has a plurality of second bottom openings and is away from the first bottom openings.

3. The electronic device according to claim 2, further comprising a storage unit disposed inside the interior and corresponding to the second bottom openings.

4. The electronic device according to claim 1, wherein the logic body has a plurality of third bottom openings adjacent to the first bottom openings.

5. The electronic device according to claim 4, wherein a size of the first bottom openings is smaller than a size of the third bottom openings.

6. The electronic device according to claim 4, wherein an aperture ratio of the first bottom openings is smaller than an aperture ratio of the third bottom openings.

7. The electronic device according to claim 4, wherein the rotating bracket does not cover or expose the third bottom openings.

8. The electronic device according to claim 4, further comprising a processing unit disposed inside the interior and corresponding to the third bottom openings.

9. The electronic device according to claim 4, further comprising a heat dissipation fan disposed inside the interior and corresponding to the third bottom openings.

10. The electronic device according to claim 1, wherein the rotating bracket has a plurality of grid perforations, wherein
in the closed mode, a gap is between the rotating bracket and the bottom, and the grid perforations are misaligned from the first bottom openings; and
in the open mode, the grid perforations are away from the first bottom openings.

11. The electronic device according to claim 1, further comprising a stopper disposed on the bottom.

12. The electronic device according to claim 11, wherein the stopper has a plurality of positioning holes, the rotating bracket has a positioning point adapted to be engaged with one of the positioning holes to fix an unfolding angle of the rotating bracket relative to the bottom.

13. The electronic device according to claim 11, wherein the stopper is rotatably disposed at the bottom.

14. The electronic device according to claim 13, wherein the rotating bracket links the stopper to rotate.

15. The electronic device according to claim 14, wherein the stopper has:
a fixed part, disposed on the bottom; and
a rotating part, disposed on the bottom and rotatably connected to a side of the fixed part, wherein the rotating bracket links the rotating part to rotate.

16. The electronic device according to claim 15, wherein the rotating part is a composite graphic columnar rotating part, a convex polygonal columnar rotating part, or a concave polygonal columnar rotating part.

17. The electronic device according to claim 15, wherein the rotating bracket has an end, a top, a ventral surface, and a back surface;
in the closed mode, the ventral surface is close to the bottom, and the top abuts against a stop surface of the rotating part; and
in the open mode, the end abuts against an external plane, and the back surface is close to a support surface of the rotating part.

18. The electronic device according to claim 17, wherein a length of the stop surface is smaller than a length of the support surface.

19. The electronic device according to claim 17, wherein the rotating bracket has a bump disposed on the back surface and adjacent to the top;
in the closed mode, the bump is separated from the rotating part; and
in the open mode, the bump abuts against the rotating part.

20. The electronic device according to claim 17, wherein the rotating bracket has an active gear part adjacent to the rotating part, and the rotating part has a passive gear part adjacent to the rotating bracket;
in the closed mode, the active gear part is meshed with the passive gear part; and
in the open mode, the active gear part is separated from the passive gear part.
